(19) United States
(12) Patent Application Publication
(10) Pub. No.: US 2008/0157179 A1
(43) Pub. Date: Jul. 3, 2008

(54) METHOD FOR FABRICATING NONVOLATILE MEMORY DEVICE

(76) Inventor: Dong-Oog Kim, Seoul (KR)

Correspondence Address: SHERR & NOURSE, PLLC, 620 HERNDON PARKWAY, SUITE 200, HERNDON, VA, 20170, US

(21) Appl. No.: 11/958,006

(22) Filed: Dec. 17, 2007

(30) Foreign Application Priority Data
Dec. 27, 2006 (KR) 10-2006-0135067

(51) Int. Cl. H01L 29/788; H01L 21/336

(52) U.S. Cl. 257/321; 438/257; 257/E21.422; 257/E29.3

(57) ABSTRACT

A nonvolatile memory device can include source selection lines, word lines, and a drain selection line formed over a substrate; spacers formed on sidewalls of the source selection lines and the drain selection line; source/drain electrodes having a lightly doped drain structure formed in the substrate; a buffer layer formed over the substrate including over the spacers; and a passivation layer composed of nitrogen gas formed over the buffer layer.

The present application claims priority under 35 U.S.C. 119 to Korean Patent Application No. 10-2006-0135067 (filed on Dec. 27, 2006), which is hereby incorporated by reference in its entirety.

### BACKGROUND

Semiconductor devices can be classified into volatile memory devices and nonvolatile memory devices. A volatile memory device may lose its data when power supply is terminated. For instance, dynamic random access memories (DRAMs) and static random access memories (SRAMs) are examples of volatile memory devices. A nonvolatile memory device may retain its data even if the power supply is terminated. For instance, erasable programmable read-only memories (EPROM) and flash memories are examples of nonvolatile memory devices.

Cycling and data retention characteristics are important for nonvolatile memory devices. In nonvolatile memory devices, cycling is the most important characteristic, and refers to no change in a characteristic despite of repetitive writing, reading and erasing of data and to repetitive injection and discharging of electrons into floating gates. Data retention means that electrons injected into the floating gates are not discharged outside.

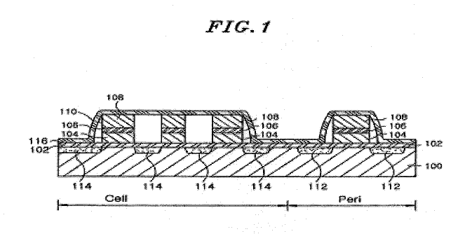

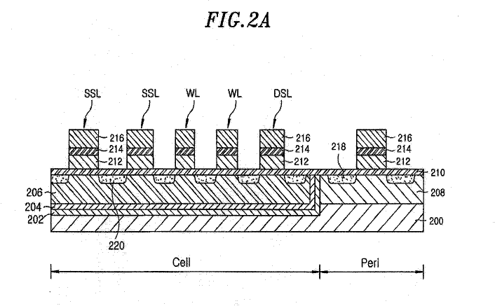

As illustrated in example FIG. 1, a nonvolatile memory device may include P-type substrate 100 divided into cell region Cell and peripheral region Peri. Tunnel oxide layer 102 may be formed on and/or over substrate 100. A source selection line (SSL), a plurality of word lines (WL) and a drain selection line (DSL) may be formed on and/or over substrate 100 in cell region Cell where tunnel oxide layer 102 is formed.

A gate pattern for a low voltage transistor (LVT) may be formed on and/or over substrate 100 in peripheral region Peri. Each of the source selection line, the drain selection line, and word line may be formed in a stacked structure including floating gate 104, gate insulation layer 106 and control gate 108.

The gate pattern for the low voltage transistor may be formed in a stacked structure including floating gate 104, gate insulation layer 106 and control gate 108. Each gate insulation layer 104 may be formed of an oxide/nitride/oxide (ONO) insulation structure in which a silicon oxide layer, a silicon nitride layer, and a silicon oxide layer are sequentially formed.

A P-type impurity may be implanted into substrate 100 disposed on both sides of the gate pattern for the low voltage transistor to form first source/drain regions 112. An N-type impurity may be implanted into substrate 100 using the source selection line, the word lines, and drain selection line as ion implantation masks to form second source/drain regions 114 on and/or over active regions of substrate 100 exposed by the source selection line, the word lines, and the drain selection line.

Spacers 110 may be formed on sidewalls of the source selection line, the word lines, and the drain selection line. Buffer oxide layer 116 may be formed on and/or over the resultant surface profile provided after formation of spacers 110. Buffer oxide layer 116 may serve to prevent damage to substrate 100 during a subsequent ion implantation process and also discharge of electrons from floating gates 104 to an external region, for instance, active regions through tunnel oxide layer 102.

An N-type impurity may be implanted with high concentration into the source region of the source selection line and the drain region of the drain selection region using spacer 110, the source selection line and the drain selection line as ion implantation masks. As a result, source/drain electrodes having a lightly doped drain (LDD) structure may be formed.

A P-type impurity may be implanted with high concentration using the gate pattern for the low voltage transistor and spacer 110 as ion implantation masks to form source/drain electrodes having an LDD structure.

During fabrication of a nonvolatile memory device, when LDD-type source/drain electrodes are formed, a masking process is performed four times, including performing a masking process twice each for forming a source/drain electrode in a peripheral region and performing a masking process twice each for forming a source/drain electrode in a cell region. As a result, a cleaning process needs to be performed four times.

After formation of buffer oxide layer 116, a cleaning process may be performed four times to form source/drain electrodes having an LDD structure. Thus, buffer oxide layer 116 may become thin, and a lattice mismatch between substrate 110 and an etch stop layer (e.g., a silicon nitride layer) may likely occur during a subsequent process of forming the etch stop layer. Moreover, the lattice mismatch may cause leakage of current. Due to the current leakage, electrons of floating gates 104 may be discharged outside through tunnel oxide layer 102. As a result, data retention and cycling characteristics of the device may be deteriorated.

### SUMMARY

Embodiments relate to a method for fabricating a nonvolatile memory device with improved characteristics by forming a passivation layer on and/or over a buffer layer (e.g., oxide-based layer) prior to forming source/drain electrodes having a lightly doped drain (LDD) structure.

Embodiments relate to a method for fabricating a nonvolatile memory device that can include at least one of the following steps: forming source selection lines, word lines, and a drain selection line over a substrate; forming impurity regions in active regions of the substrate; forming spacers on sidewalls of the source selection lines and the drain selection line; forming a buffer layer over the substrate including over the spacers; forming a passivation layer over the buffer layer; and then forming source/drain electrodes by implanting a high concentration impurity into the impurity regions using the spacers, the source selection lines, and the drain selection line as ion implantation masks. In accordance with embodiments, the impurity regions can include a source region of the source selection lines and a drain region of the drain selection line.

Embodiments relate to a method for fabricating a nonvolatile memory device that can include at least one of the following steps: forming a pair of source selection lines, a pair of word lines and a drain selection line over a substrate; forming spacers on sidewalls of the source selection lines and the drain selection line; forming a buffer layer over the substrate including the source selection lines, the word lines and the drain selection line; forming a passivation layer over the buffer layer by performing a first annealing process; forming source/drain electrodes having a lightly doped drain structure in the substrate; and then increasing the density of the passivation layer by performing a second annealing process on the substrate.

Embodiments relate to a nonvolatile memory device that can include at least one of the following: a pair of source selection lines, a pair of word lines, and a drain selection line formed over a substrate; impurity regions formed in active regions of the substrate; spacers formed on sidewalls of the source selection lines and the drain selection line; source/drain electrodes having a lightly doped drain structure formed in the substrate; and a buffer layer formed over the substrate including the spacers; and a passivation layer formed over the buffer layer.

### DRAWINGS

Example FIG. 1 illustrates a metal oxide semiconductor (MOS) transistor.

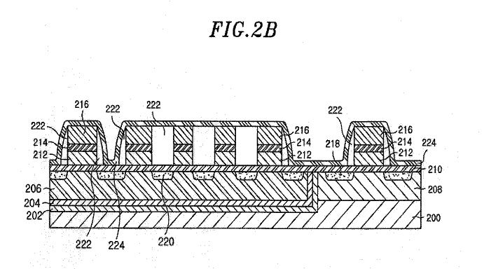

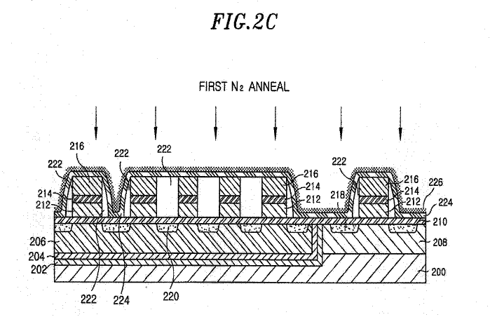

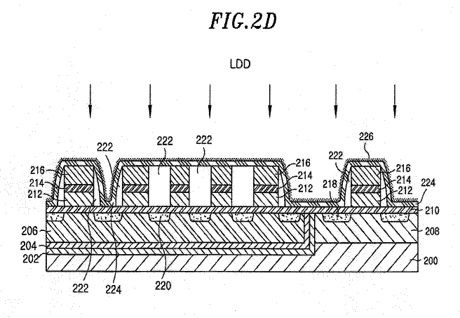

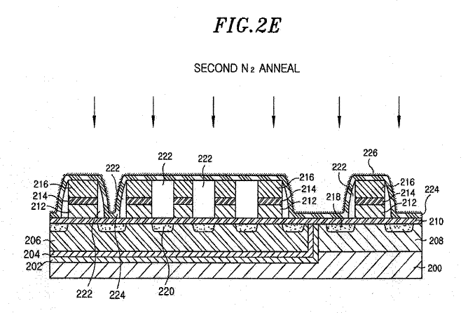

Example FIGS. 2A to 2E illustrate a method for fabricating a MOS transistor, in accordance with embodiments.

### DESCRIPTION

As illustrated in example FIG. 2A, a nonvolatile memory device provided in accordance with embodiments can include P-type substrate 200 divided into cell region Cell and peripheral region Peri. Triple N-type well 202 can be formed on and/or over cell region CELL of substrate 100. Deep P-type well 204 can be formed on and/or over triple N-type well 202. Shallow P-type well 206 can be formed on and/or over deep P-type well 204. N-type well 208 can be formed on and/or over substrate 200 in peripheral region Peri.

A device isolation structure defining a plurality of active regions arranged in parallel can be formed in a given region of substrate 200. The device isolation structure can be formed by a local oxidation of silicon (LOCOS) process or a trench isolation process.

Tunnel layer 210 can be formed on and/or over the active regions of substrate 200. Tunnel layer 210 can be composed of an oxide-based material.

Source selection lines SSL, multiple word lines WL and drain selection line DSL can be formed on and/or over substrate 200 including tunnel layer 210 in cell region Cell. A gate pattern for a low voltage transistor can be formed over substrate 200 in peripheral region Peri.

Each of source selection lines SSL, drain selection line DSL and multiple word lines WL can be formed in a stacked structure including floating gate 212, gate insulation layer 214, and control gate 216. The gate pattern for the low voltage transistor can also be formed in a stacked structure including floating gate 212, gate insulation layer 214, and control gate 216.

Floating gates 212 and control gates 216 can each be composed of a polysilicon-based material. Gate insulation layers 214 can have an oxide/nitride/oxide (ONO) insulation structure including a silicon oxide layer, a silicon nitride layer, and a silicon oxide layer.

A P-type impurity can be implanted into substrate 200 disposed on both sides of the gate pattern for the low voltage transistor to form first impurity regions 218. An N-type impurity can be implanted into the active regions of substrate 200 using source selection lines SSL, word lines WL, and drain selection line DSL as ion implantation masks to form second impurity regions 220. One of second impurity regions 220 that is adjacent to source selection lines SSL and formed over one of the active regions opposite to one word line WL can serve as a source region of source selection lines SSL. Another second impurity region 220 adjacent to drain selection line DSL and formed over another active region opposite to word lines WL can serve as a drain region of drain selection line DSL.

As illustrated in example FIG. 2B, an insulation layer that can be composed of tetraethyl orthosilicate (TEOS), can be formed on and/or over the resultant surface profile illustrated in example FIG. 2A. An etch-back process can then be performed on the insulation layer to form spacers 222 on sidewalls of source selection lines SSL, drain selection line DSL, and the gate pattern for the low voltage transistor.

Buffer layer 224 can then be formed on and/or over substrate 200 where spacers 222 are formed. Buffer layer 224 can be composed of an oxide-based material and can serve to prevent damage to substrate 200 during a subsequent ion implantation process and discharge of electrons from floating gates 212 to the outside, for instance, active regions through tunnel layer 210.

As illustrated in example FIG. 2C, a first annealing process can then be performed on the resultant structure provided after formation of buffer layer 224 to form nitrogen (N₂) passivation layer 226. The first annealing process can be conducted using nitrogen (N₂) gas.

As illustrated in example FIG. 2D, an N-type impurity can then be implanted with high concentration into a group of second impurity regions 220 (i.e., the source region of source selection lines SSL and the drain region of drain selection line DSL) using spacers 222, source selection lines SSL and drain selection line DSL as ion implantation masks to from first source/drain electrodes having a lightly doped drain (LDD) structure.

A P-type impurity can then be implanted with high concentration into first impurity regions 218 using the gate pattern for the low voltage transistor and spacers 222 as ion implantation masks to form second source/drain electrodes having an LDD structure.

When source/drain electrodes are formed having an LDD structure, a masking process is performed four times, including performing a masking process twice each for forming a source/drain electrode in a peripheral region, and performing a masking process twice each for forming a source/drain electrode in a cell region. As a result, a cleaning process needs to be performed four times.

Nitrogen N₂ passivation layer 226 can be advantageous as preventing damage to buffer layer 224 during the cleaning process when forming the first and second LDD source/drain electrodes. Instead, nitrogen N₂ passivation layer 226 is partially damaged during the formation of the first and second LDD source/drain electrodes.

As illustrated in example FIG. 2E, a second annealing process using N₂ gas can then be performed over substrate 200 where buffer layer 224 is formed. As a result, the density of nitrogen N₂ passivation layer 226 can be enhanced.

In accordance with embodiments, after formation of buffer layer 224, a first N₂ annealing process can be performed prior to forming the first and second LDD source/drain electrodes to form nitrogen (N₂) passivation layer 226. After formation of the first and second LDD source/drain electrodes, a second N₂ annealing process can be performed in order that N₂ passivation layer 226 can further protect buffer layer 224. As a result of this protection, electrons do not leak through an edge portion of the active regions, and electrons of floating gates 212 cannot be discharged outside through tunnel layer 210. Accordingly, cycling and data retention characteristics of the nonvolatile memory device can be improved.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming source selection lines, word lines, and a drain selection line over a substrate;
forming impurity regions in active regions of the substrate;
forming spacers on sidewalls of the source selection lines and the drain selection line;
forming a buffer layer over the substrate including over the spacers;
forming a passivation layer over the buffer layer; and then forming source/drain electrodes by implanting a high concentration into the impurity regions using the spacers, the source selection lines, and the drain selection line as ion implantation masks,
wherein the impurity regions includes a source region of the source selection lines and a drain region of the drain selection line.

2. The method of claim 1, further comprising increasing the density of the passivation layer by performing an annealing process on the substrate.

3. The method of claim 2, where the annealing process is performed on the substrate where the source/drain electrodes are formed.

4. The method of claim 1, wherein forming the passivation layer over the buffer layer comprises performing an annealing process.

5. The method of claim 4, wherein the annealing process uses N₂ gas.

6. The method of claim 2, wherein forming the passivation layer over the buffer layer comprises performing an annealing process.

7. The method of claim 6, wherein the annealing process uses N₂ gas.

8. The method of claim 1, wherein the buffer layer includes an oxide-based material.

9. The method of claim 1, wherein the passivation layer comprises N₂.

10. An apparatus comprising:
a pair of source selection lines, a pair of word lines, and a drain selection line formed over a substrate;
impurity regions formed in active regions of the substrate;
spacers formed on sidewalls of the source selection lines and the drain selection line;
source/drain electrodes having a lightly doped drain structure formed in the substrate;
a buffer layer formed over the substrate including the spacers; and
a passivation layer formed over the buffer layer.

11. The apparatus of claim 10, wherein the source selection lines, the drain selection line, the word lines and the low voltage transistor include gate patterns having a stacked structure.

12. The apparatus of claim 11, wherein the stacked structure comprises a floating gate formed over the tunnel layer, a gate insulation layer formed over the gate layer and a control gate formed over the gate insulation layer.

13. The apparatus of claim 12, wherein the floating gate and the control gate are each composed of a polysilicon-based material.

14. The apparatus of claim 13, wherein the gate insulation layer has an oxide/nitride/oxide structure including a silicon oxide layer, a silicon nitride layer, and a silicon oxide layer.

15. The apparatus of claim 10, wherein the buffer layer is composed of an oxide-based material.

16. The apparatus of claim 10, wherein the passivation layer is composed of nitrogen gas.

17. A method comprising:
forming a pair of source selection lines, a pair of word lines and a drain selection line over a substrate;
forming spacers on sidewalls of the source selection lines and the drain selection line;
forming a buffer layer over the substrate including the source selection lines, the word lines and the drain selection line;
forming a passivation layer over the buffer layer by performing a first annealing process;
forming source/drain electrodes having a lightly doped drain structure in the substrate; and then increasing the density of the passivation layer by performing a second annealing process on the substrate.

18. The method of claim 17, wherein the passivation layer comprises N₂.

19. The method of claim 18, wherein the first annealing process and the second annealing process uses N₂.

20. The method of claim 17, wherein the first annealing process and the second annealing process uses N₂.
